(19) United States
(12) Patent Application Publication
(10) Pub. No.: US 2009/0167362 A1
(43) Pub. Date: Jul. 2, 2009

(54) COMPARATOR

(75) Inventors: Szu-Kang Hsien, Taoyuan County (TW); Yun Chiu, Urbar, IL (US)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: INDUSTRIAL TECHNOLOGY RESEARCH INSTITUTE, Hsinchu (TW)

(21) Appl. No.: 11/965,738

(22) Filed: Dec. 28, 2007

(51) Int. Cl. H03K 5/22

(52) U.S. Cl. 327/64

(57) ABSTRACT

A comparator is provided. In a first period, input terminal of the pre-amplifier is coupled to a first voltage. A first terminal of the first capacitor is coupled to the second input terminal of the pre-amplifier. A second terminal of the first capacitor is coupled to the first input voltage in the first period, and is coupled to the second input voltage in the second period. The second capacitor is coupled between the output terminal of the pre-amplifier and an input terminal of the gain unit. The switch is coupled between the input terminal and an output terminal of the gain unit. An input terminal of the latch is coupled to the output terminal of the gain unit. The latch outputs a comparison result.

### BACKGROUND OF THE INVENTION

1. Field of the Invention

The present invention generally relates to a comparator.

2. Description of Related Art

Various electronic devices usually use comparators to perform voltage level comparison. For example, in an analog-to-digital converter, usually multiple comparators are disposed for comparing an input voltage and a reference voltage. With the improvement of the communication network bandwidth, the conversion speed of the analog-to-digital circuit adapted to the front end is increasingly improved so as to meet the requirements of the overall system. Therefore, it is the inevitable trend to develop the high-speed comparator with the offset cancellation function.

FIG. 1 is a circuit block diagram of a conventional comparator. The comparator 100 includes a pre-amplifier 110 and a latch 120. The comparator 100 receives and compares an input voltage Vi and a reference voltage Vref, and outputs a comparison result Vout depending on a potential relation between the input voltage Vi and the reference voltage Vref. In an actual circuit, the comparator 100 usually has an offset voltage (Vos in FIG. 1).

FIG. 2 is a circuit diagram of a comparator of US patent publication NO. U.S. Pat. No. 4,691,189. The details of the operation processes thereof will not be described herein. Referring to FIG. 2, in the course of calibration, switches SW21, SW23, SW24 are turned on. The turned-on switches SW23, SW24 make the amplifiers A21, A22 to form a closed loop, respectively. Here, only a calibration mechanism of the signal Vout1 is illustrated, and the signal Vout2 also has the same calibration mechanism. In FIGS. 2A and 2B, “Vos” connected to a positive input terminal indicates the input offset voltage of the amplifier A21.

FIG. 2A illustrates an equivalent configuration of the first stage amplifier A21 when the switches SW21, SW23 are turned on while the switch SW22 is turned off in FIG. 2. In this period, i.e., an autozeroing phase, the output Vout1 of the amplifier A21 satisfies Vout1=A₂₁(Vos−Vout1), where A₂, is the gain value of the amplifier A21. Thus, Vout1=Vos(A₂₁/(1+A₂₁)). If the gain value A₂, of the amplifier A21 is large enough, the output Vout1 of the amplifier A21 is more or less equal to the input offset voltage Vos.

FIG. 2B illustrates an equivalent configuration of the first stage amplifier A21 when the switches SW21, SW23 are turned off while the switch SW22 is turned on in FIG. 2. Referring to FIG. 2B, it is assumed that the voltage at a negative input terminal of the amplifier A21 is Vx. In this period, i.e., a sampling phase, a potential difference stored in the capacitor C21 satisfies Vx−Vi=Vos−Vref. Thus, the voltage Vx at the negative input terminal of the amplifier A21 satisfies Vx=Vi−Vref+Vos. The output Vout1 of the amplifier A21 satisfies Vout1=A₂₁(Vos−Vx)=A₂₁(Vref−Vi).

Among the prior arts, the US patent publication NO. U.S. Pat. No. 4,748,418 is similar to the above U.S. Pat. No. 4,691,189. FIG. 3 is a circuit diagram of a comparator of the US patent publication NO. U.S. Pat. No. 4,899,068. The details of the operation processes thereof will not be described herein. “Vos” indicates the input offset voltage in the amplifier A31. Referring to FIG. 3, in the course of calibration (autozeroing phase), switches SW31, SW34, SW35 are turned on. FIG. 3A illustrates an equivalent configuration of an amplifier A31 when switches SW31, SW34, SW35 are turned on while switches SW32, SW33 are turned off in FIG. 3. The turned-on switch SW35 makes the amplifier A31 to form a closed loop. Thus, the output Vout of the amplifier A31 satisfies Vout=A₃₁(Vos-Vout), where A₃₁ is the gain value of the amplifier A31. Thus, Vout=Vos(A₃₁/(1+A₃₁)). If the gain value A₃₁ of the amplifier A21 is large enough, the output Vout of the amplifier A31 is more or less equal to the input offset voltage Vos.

FIG. 3B illustrates an equivalent configuration of the amplifier A31 when the switches SW31, SW34, SW35 are turned off while the switches SW32, SW33 are turned on in FIG. 3. Referring to FIG. 3B, it is assumed that the voltage at a negative input terminal of the amplifier A31 is Vx. In this period, i.e., the sampling phase, the amount of the electric charge Q stored in capacitors C31, C32 satisfies Q=C₃₁(Vos−Vi)+C₃₂(Vos)=C₃₁(Vx)+C₃₂(Vx−Vref), where C₃₁ is the capacitance of the capacitor C31, and C₃₂ is the capacitance of the capacitor C32. Thus, the voltage Vx at the negative input terminal of the amplifier A31 satisfies Vx=Vos+Vref(C₃₂/(C₃₁+C₃₂))−Vi(C₃₁/(C₃₁+C₃₂)). The output Vout of the amplifier A31 satisfies Vout=A₃₁(Vos−Vx)=A₃₁(C₃₁Vi−C₃₂Vref)/(C₃₁+C₃₂).

Among the prior arts, US patent publication NO. U.S. Pat. No. 5,514,972, U.S. Pat. No. 6,396,429, U.S. Pat. No. 6,608,503 are similar to the U.S. Pat. No. 4,899,068.

### SUMMARY OF THE INVENTION

Accordingly, one example consistent with the present invention is directed to a comparator for comparing a first input voltage and a second input voltage and outputting a comparison result. The comparator includes a pre-amplifier, a first capacitor, a second capacitor, a gain unit, a switch, and a latch. The pre-amplifier has a first input terminal, a second input terminal, and an output terminal. In a first period, the second input terminal of the pre-amplifier is coupled to a first voltage. A first terminal of the first capacitor is coupled to the second input terminal of the pre-amplifier. A second terminal of the first capacitor is coupled to the first input voltage in the first period, and is coupled to the second input voltage in the second period. A first terminal of the second capacitor is coupled to the output terminal of the pre-amplifier. An input terminal of the gain unit is coupled to a second terminal of the second capacitor. Two terminals of the switch are respectively coupled to the input terminal and an output terminal of the gain unit. An input terminal of the latch is coupled to the output terminal of the gain unit, and an output terminal of the latch provides a comparison result.

One example consistent with the present invention provides a comparator for comparing a first differential input voltage and a second differential input voltage and outputting a comparison result. The comparator includes a pre-amplifier, a first capacitor, a second capacitor, a third capacitor, a fourth capacitor, a first gain unit, a second gain unit, a first switch, a second switch, and a latch. The pre-amplifier has a first input terminal, a second input terminal, a first output terminal, and a second output terminal. In a first period, the first and the second input terminal of the pre-amplifier are both coupled to a first voltage. First terminals of the first and the third capacitor are respectively coupled to the second and the first input terminal of the pre-amplifier. In the first period, second terminals of the first and the third capacitor are optionally coupled to a first terminal and a second terminal of the first differential input voltage. In a second period, the second terminals of the first and the third capacitor are coupled to a first terminal and a second terminal of the second differential input voltage. First terminals of the second and the fourth capacitor are respectively coupled to the second and the first output terminal of the pre-amplifier. Input terminals of the first and the second gain unit are respectively coupled to second terminals of the second and the fourth capacitor. Two terminals of the first switch are respectively coupled to the input terminal and an output terminal of the first gain unit. Two terminals of the second switch are respectively coupled to the input terminal and an output terminal of the second gain unit. A first and a second input terminal of the latch are respectively coupled to the output terminals of the first and the second gain unit, and an output terminal of the latch provides the comparison result.

One example consistent with the present invention provides a comparator, which meets the requirement of the high-speed comparison operation, and can cancel the offset voltage.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a circuit block diagram of a conventional comparator.

FIG. 2 is a comparator circuit diagram of US patent publication NO. U.S. Pat. No. 4,691,189.

FIG. 2A illustrates an equivalent configuration of the first stage amplifier A21 when the switches SW21, SW23 are turned on while the switch SW22 is turned off in FIG. 2.

FIG. 2B illustrates an equivalent configuration of the first stage amplifier A21 when the switches SW21, SW23 are turned off while the switch SW22 is turned on in FIG. 2.

FIG. 3 is a comparator circuit diagram of US patent publication NO. U.S. Pat. No. 4,899,068.

FIG. 3A illustrates an equivalent configuration of the amplifier A31 when the switches SW31, SW34, SW35 are turned on while the switches SW32, SW33 are turned off in FIG. 3.

FIG. 3B illustrates an equivalent configuration of the amplifier A31 when the switches SW31, SW34, SW35 are turned off while the switches SW32, SW33 are turned on in FIG. 3.

FIG. 4 illustrates an implementation example of a high-speed comparator with offset cancellation function according to the present invention.

FIG. 4A is a timing diagram of turning on/off of the switches SW41-SW44 in FIG. 4.

FIG. 4B is an equivalent circuit diagram of the comparator 400 in FIG. 4 in a first period T1.

FIG. 4C is an equivalent circuit diagram of the comparator 400 in FIG. 4 in a second period T2.

FIG. 5 illustrates a high-speed differential signal comparator with offset cancellation function according to an embodiment of the present invention.

FIG. 5A is a timing diagram of turning on/off of the switches SW51-SW58 in FIG. 5.

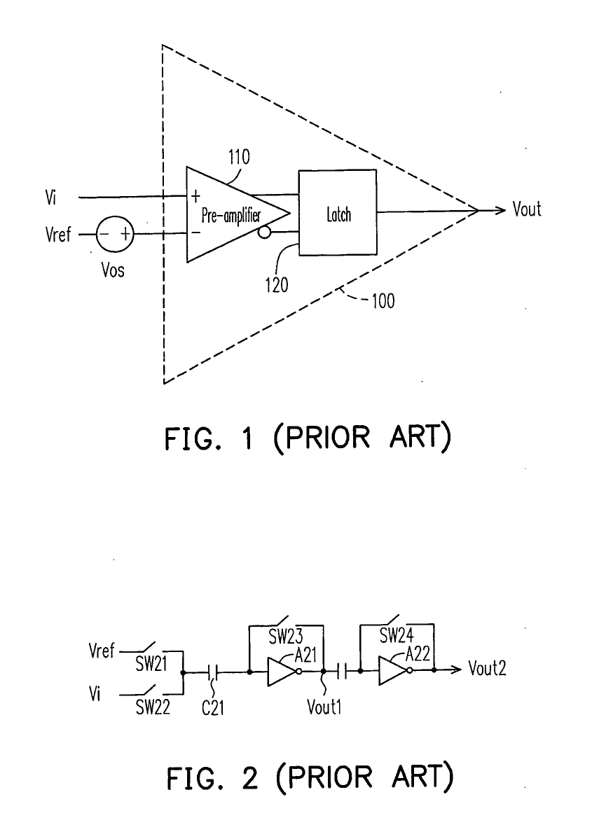

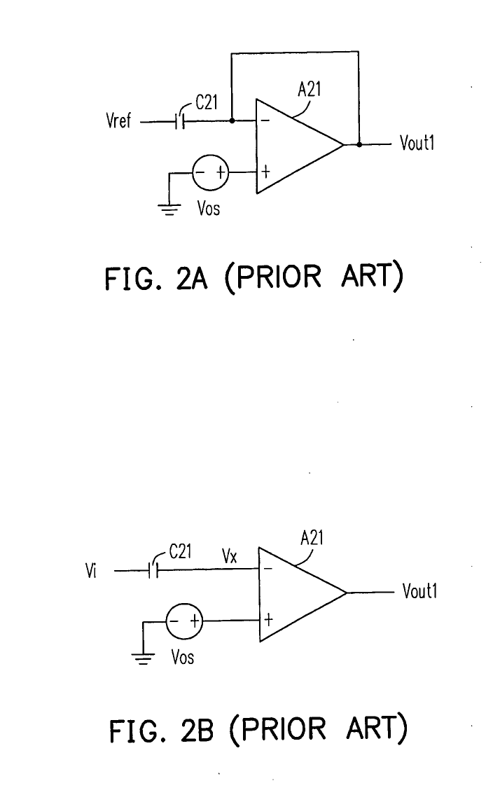

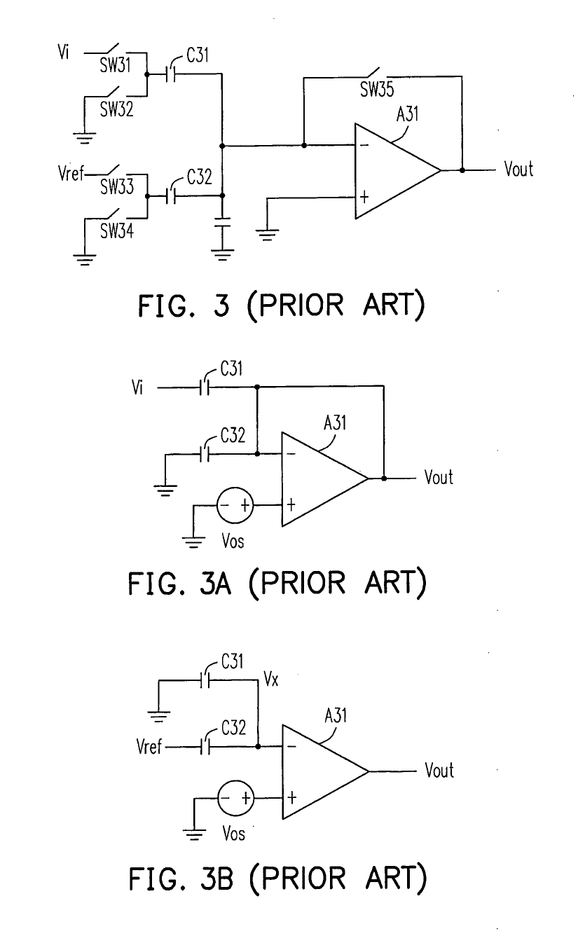

### DESCRIPTION OF THE EMBODIMENTS

Reference will now be made in detail to the exemplary embodiments of the invention, examples of which are illustrated in the accompanying drawings. Wherever possible, the same reference numbers are used in the drawings and the description to refer to the same or like parts.

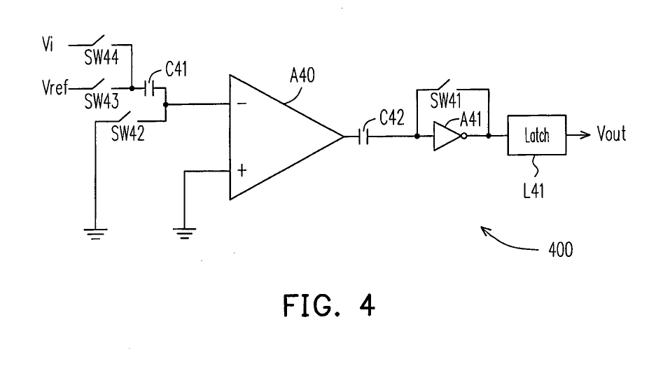

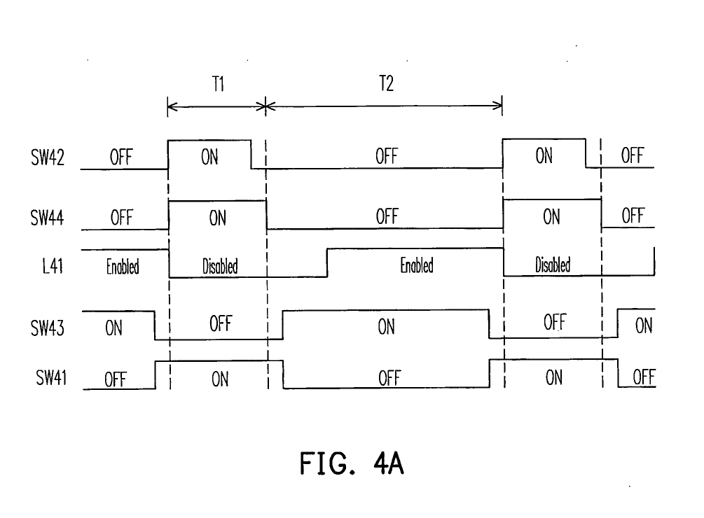

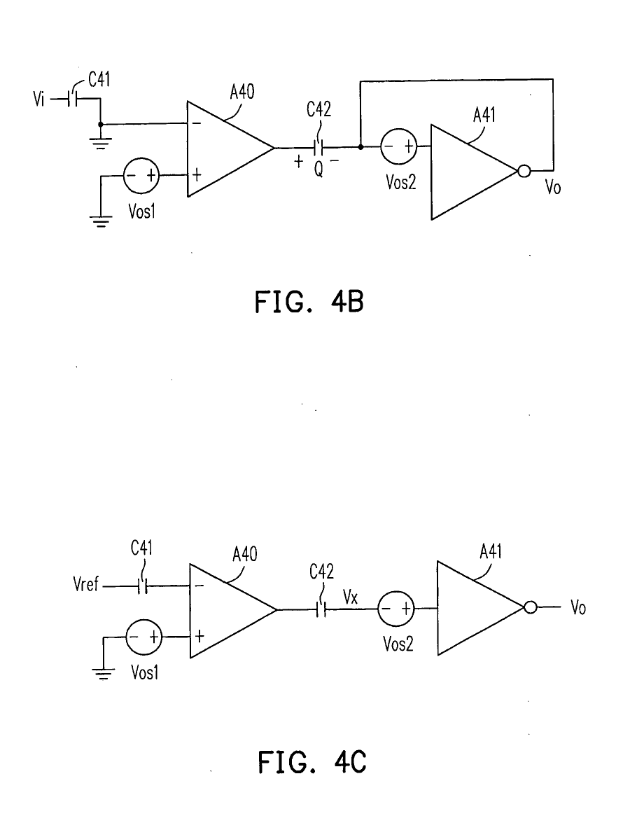

FIG. 4 illustrates an implementation example of a high-speed comparator with offset cancellation function according to the present invention. Referring to FIG. 4, the comparator 400 compares a first input voltage Vi and a second input voltage Vref and outputs a comparison result Vout. The comparator 400 includes a pre-amplifier A40, a first capacitor C41, a second capacitor C42, a gain unit A41, switch SW41-SW44, and a latch L41. In FIG. 4, “Vos1” is the input offset voltage in the amplifier A40 (e.g., an operational amplifier). A first terminal of the first capacitor C41 is coupled to a second input terminal (hereafter, the negative input terminal) of the pre-amplifier A40. A first terminal of the second capacitor C42 is coupled to an output terminal of the pre-amplifier A40. An input terminal of the gain unit A41 (e.g. the inverter, buffer, or amplifier) is coupled to a second terminal of the second capacitor C42. Two terminals of the switch SW41 are respectively coupled to the input terminal and an output terminal of the gain unit A41. An input terminal of the latch L41 is coupled to the output terminal of the gain unit A41.

In a first period T1, the negative input terminal of the pre-amplifier A40 and first terminal of the first capacitor C41 are coupled to a grounding voltage. A second terminal of the first capacitor C41 is coupled to the first input voltage V1 in the first period T1. The positive input terminal of the pre-amplifier A40 is always coupled to a grounding voltage. The switch SW41 is turned on in the first period T1. The latch L41 is disabled in the first period T1.

In a second period T2, the second terminal of the first capacitor C41 is coupled to the second input voltage Vref in the second period T2. The switch SW41 is turned off in the second period T2. The latch L41 is enabled in the second period T2. At this time, an output terminal of the latch L41 provides the comparison result to a next stage circuit (not known).

The operations in the first period T1 and the second period T2 may be implemented in any manner, and the switches SW42, SW43, SW44, in FIG. 4 may be one of the implementations. The second switch SW42 is coupled to the negative input terminal of the pre-amplifier A40, for coupling the grounding voltage to the negative input terminal of the pre-amplifier A40 and first terminal of the first capacitor C41 in the first period T1. The fourth switch SW44 is coupled to the second terminal of the first capacitor C41, for coupling the first input voltage V1 to the second terminal of the first capacitor C41 in the first period T1. The third switch SW43 is coupled to the second terminal of the first capacitor C41, for coupling the second input voltage Vref to the second terminal of the first capacitor C41 in the second period T2.

FIG. 4A is a timing diagram of turning on/off of the switches SW41-SW44 in FIG. 4. Referring to FIG. 4 and FIG. 4A, in the first period T1, the switches SW42, SW44 are both turned on, and the switch SW43 turned off. At this time, the latch L41 is disabled. FIG. 4B is an equivalent circuit diagram of the comparator 400 in FIG. 4 in the first period T1. In FIG. 4B, “Vos1” connected to the positive voltage of pre-amplifier A40 and “Vos2” connected to the input of gain unit A41 indicates theirs input offset voltages. In this period, Vos2=−(1+1/A₄₁)Vout. If the gain value A₄₁ of the amplifier A41 is large enough, the output Vo of the amplifier A41 is more or less equal to the input offset voltage Vos2 with a minus sign. Thus, the amount of the electric charge Q stored in the capacitor C42 satisfies Q=C₄₂(A₄₀Vos1+Vos2), where A₄₀ is the gain value of the amplifier A40, and C₄₂ is the capacitance of the capacitor C42.

After the first period T1 ends, the switches SW41 and SW42 are first turned off to achieve bottom-plate sampling, and then the switch SW43 is turned off. During T2 period, the switch SW43 is turned on and after a finite amount of time, the latch L41 is enabled. FIG. 4C is an equivalent circuit diagram of the comparator 400 in FIG. 4 in the second period T2. In this period, the amount of electric charge Q stored in the capacitor C42 satisfies, Q=C₄₂(A₄₀Vos1+Vos2)=C₄₂[A₄₀(Vos1−Vref+Vi)−Vx], thus Vx=A₄₀(Vref−Vi)−Vos2 and the output voltage Vo of the gain unit A41 is Vo=−A₄₁ (Vx+Vos2)=A₄₀A₄₁(Vi−Vref).

Based on the circuit analysis, it is known that the comparator 400 may cancel the offset voltage and perform the high-speed comparison operation. Those of ordinary skill in the art can implement the present invention in other manners with reference to the teachings of the above embodiments. For example, the comparator 400 is a comparator for a single-ended signal. Those of ordinary skill in the art can implement the comparator for a differential signal according to the spirit of the present invention.

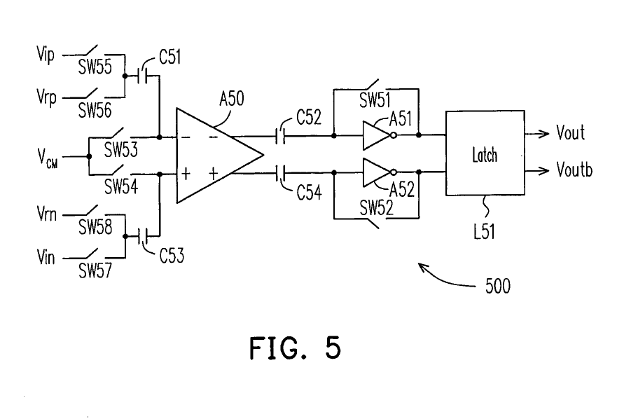

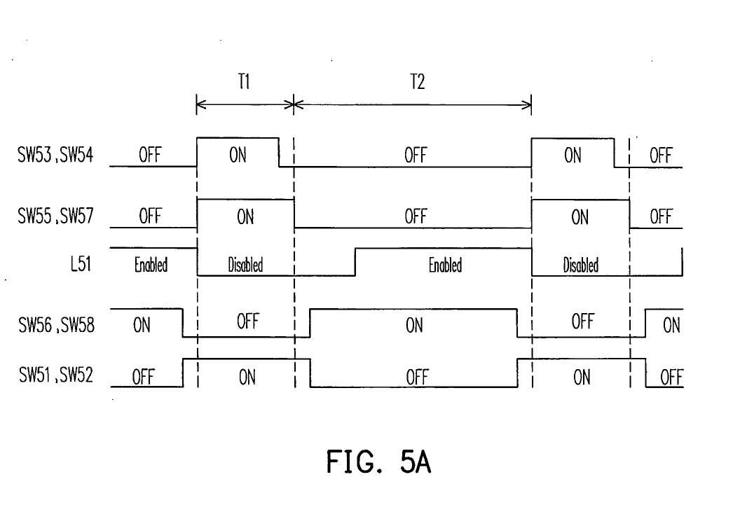

FIG. 5 illustrates a high-speed differential signal comparator with offset cancellation function according to an embodiment of the present invention. Referring to FIG. 5, the comparator 500 may compare a first differential input voltage (i.e., the first terminal signal Vip and the second terminal signal Vin) and a second differential input voltage (i.e., the first terminal signal Vrp and the second terminal signal Vrn) and output the comparison result Vout (or an inverted result Voutb). The analysis of the offset cancellation function of the comparator 500 will not be repeated in this embodiment, and may be known with reference to the illustration of the previous embodiment.

The comparator 500 includes a pre-amplifier A50, a first capacitor C51, a second capacitor C52, a third capacitor C53, a fourth capacitor C54, a first gain unit A51, a second gain unit A52, switch SW51-SW58, and a latch L51. The pre-amplifier A50 (e.g., the operational amplifier) has a first input terminal (hereafter, a positive input terminal), a second input terminal (hereafter, a negative input terminal), a first output terminal (hereafter, a positive output terminal), and a second output terminal (hereafter, a negative output terminal). In the first period T1, the positive and the negative input terminal of the pre-amplifier A50 are both coupled to the first voltage (hereafter, the common voltage V_{CM} of the constant potential).

A first terminal of the capacitor C51 is coupled to the negative input terminal of the pre-amplifier A50. A second terminal of the capacitor C51 is coupled to the first terminal Vip of the first differential input voltage in a first period T1, and is coupled to the first terminal Vrp of the second differential input voltage in a second period T2. A first terminal of the capacitor C53 is coupled to the positive input terminal of the pre-amplifier A50. A second terminal of the capacitor C53 is coupled to the second terminal Vin of the first differential input voltage in the first period T1, and is coupled to the second terminal Vrn of the second differential input voltage in the second period T2. A first terminal of the capacitor C52 is coupled to the negative output terminal of the pre-amplifier A50. A first terminal of the capacitor C54 is coupled to the positive output terminal of the pre-amplifier A50.

An input terminal of the gain unit A51 (e.g., an inverter, a buffer, or an amplifier) is coupled to a second terminal of the capacitor C52. An input terminal of the gain unit A52 is coupled to a second terminal of the capacitor C54. Two terminals of the switch SW51 are respectively coupled to the input terminal and an output terminal of the gain unit A51. Two terminals of the switch SW52 are respectively coupled to the input terminal and an output terminal of the gain unit A52. The switches SW51, SW52 are turned on in the first period T1, and are turned off in the second period T2. A first input terminal of the latch L51 is coupled to an output terminal of the gain unit A51, and a second input terminal of the latch L51 is coupled to an output terminal of the gain unit A52. The latch L51 is disabled in the first period T1, and is enabled in the second period T2. Thus, an output terminal of the latch L51 may provide the comparison result Vout and/or the inverted result Voutb.

The operations in the first period T1 and the second period T2 may be implemented in any manner, and the switches SW53, SW54, SW55, SW56, SW57, SW58 in FIG. 5 may be one of the implementations. The third switch SW53 is coupled to the negative input terminal of the pre-amplifier A50, and the fourth switch SW54 is coupled to the positive input terminal of the pre-amplifier A50. In the first period T1, the switches SW53, SW54 couple the common voltage V_{CM} to the positive and the negative input terminal of the pre-amplifier A50 as well as to the second terminal of C51 and C53. In the second period T2, the switches SW53, SW54 are turned off. In the first period T1, the switches SW55, SW57 couple the first terminal Vip and the second terminal Vin of the first differential input voltage to the second terminals of the first capacitor C51 and the third capacitor C53, respectively, and the switches SW56, SW58 are turned off. In the second period T2, the switches SW56, SW58 optionally couple the first terminal Vrp and the second terminal Vrn of the second differential input voltage to the second terminal of the first capacitor C51 and the third capacitor C53, and the switches SW55, SW57 are turned off.

FIG. 5A is a timing diagram of turning on/off of the switches SW51-SW58 in FIG. 5. Referring to FIGS. 5 and 5A together, in the first period T1, the switches SW51, SW52, SW53, SW54, SW55, SW57 are both turned on, and the switches SW56, SW58 are turned off. At this time, the latch L51 may be controlled to be disabled. In the first period T1, the first terminal Vip and the second terminal Vin of the first differential input voltage are respectively sampled and stored in the capacitors C51, C53, and the offset voltage of the pre-amplifier A50 is stored in the capacitors C52, C54 by a gain factor of A₅₀. A₅₀ is the gain value of the pre-amplifier A50. The gain value A₅₀ can not be too large, thus the input terminals of the gain units A51, A52 may not be saturated. In addition, since the switches SW51, SW52 are turned on, the gain units A51, A52 realize “autozeroing”, such that the offset voltages of the gain units A51, A52 are respectively stored in the capacitors C52, C54.

After the first period T1 ends, the switches SW53, SW54 must be first turned off, and then the switches SW55, SW57 are turned off thus removed signal dependent charge injection. SW51 and SW52 use the same clock phase as SW53 and SW54 to make sure there is no signal dependent charge injection. After the switches SW55, SW57, SW51 and SW52 are turned off, the switches SW56, SW58 are turned on. Thus, the difference between the first differential input voltages (Vip and Vin) and the second differential input voltages (Vrp and Vrn) is amplified by the pre-amplifier A50 and the gain units A51, A52. SW56 and SW58 should turn off after the latch L51 regenerates the signal from the outputs of A51 and A52 which will not disturb the latch regeneration process. Based on the amplified (Vip-Vrp) and (Vin-Vrn), the latch L51 may output the comparison result Vout and/or the inverted result Voutb. Thus, the comparator 500 can meet the requirement of the high-speed comparison operation, and cancel the offset voltage.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A comparator, for comparing a first input voltage and a second input voltage and outputting a comparison result, comprising:
a pre-amplifier, comprising a first input terminal, a second input terminal, and an output terminal, wherein the second input terminal of the pre-amplifier is coupled to a first voltage in a first period;
a first capacitor, comprising a first terminal coupled to the second input terminal of the pre-amplifier, and a second terminal coupled to the first input voltage in the first period, and coupled to the second input voltage in a second period;
a second capacitor, comprising a first terminal coupled to the output terminal of the pre-amplifier;
a gain unit, comprising an input terminal coupled to a second terminal of the second capacitor;
a switch, comprising two terminals respectively coupled to the input terminal and an output terminal of the gain unit; and
a latch, comprising an input terminal coupled to the output terminal of the gain unit, and an output terminal for providing the comparison result.

2. The comparator according to claim 1, further comprising:
a second switch, coupled to the second input terminal of the pre-amplifier, for coupling the first voltage to the second input terminal of the pre-amplifier in the first period.

3. The comparator according to claim 1, further comprising:
a fourth switch, coupled to the second terminal of the first capacitor, for coupling the first input voltage to the second terminal of the first capacitor in the first period; and
a third switch, coupled to the second terminal of the first capacitor, for coupling the second input voltage to the second terminal of the first capacitor in the second period.

4. The comparator according to claim 1, wherein the switch is turned on in the first period, and is turned off in the second period.

5. The comparator according to claim 1, wherein the latch is disabled in the first period, and is enabled in the second period.

6. A comparator, for comparing a first differential input voltage and a second differential input voltage and outputting a comparison result, comprising:
a pre-amplifier, comprising a first input terminal, a second input terminal, a first output terminal, and a second output terminal, wherein the first and the second input terminal of the pre-amplifier are both optionally coupled to a first voltage in a first period;
a first capacitor, comprising a first terminal coupled to the second input terminal of the pre-amplifier, and a second terminal optionally coupled to a first terminal of the first differential input voltage in the first period, and optionally coupled to a first terminal of the second differential input voltage in a second period;
a second capacitor, comprising a first terminal coupled to the second output terminal of the pre-amplifier;
a third capacitor, comprising a first terminal coupled to the first input terminal of the pre-amplifier, and a second terminal optionally coupled to a second terminal of the first differential input voltage in the first period, and optionally coupled to a second terminal of the second differential input voltage in the second period;
a fourth capacitor, comprising a first terminal coupled to the first output terminal of the pre-amplifier;
a first gain unit, comprising an input terminal coupled to a second terminal of the second capacitor;
a second gain unit, comprising an input terminal coupled to a second terminal of the fourth capacitor;
a first switch, comprising two terminals respectively coupled to the input terminal and an output terminal of the first gain unit;
a second switch, comprising two terminals respectively coupled to the input terminal and an output terminal of the second gain unit; and
a latch, comprising a first input terminal coupled to the output terminal of the first gain unit, a second input terminal coupled to the output terminal of the second gain unit, and an output terminal for providing the comparison result.

7. The comparator according to claim 6, further comprising:
a third switch, coupled to the second input terminal of the pre-amplifier, for coupling the first voltage to the second input terminal of the pre-amplifier in the first period; and
a fourth switch, coupled to the first input terminal of the pre-amplifier, for coupling the first voltage to the first input terminal of the pre-amplifier in the first period.

8. The comparator according to claim 6, further comprising:
a fifth switch, coupled to the second terminal of the first capacitor, for coupling the first terminal of the first differential input voltage to the second terminal of the first capacitor in the first period; and
a sixth switch, coupled to the second terminal of the first capacitor, for coupling the first terminal of the second differential input voltage to the second terminal of the first capacitor in the second period.

9. The comparator according to claim 6, further comprising:
a seventh switch, coupled to the second terminal of the third capacitor, for coupling the second terminal of the first differential input voltage to the second terminal of the third capacitor in the first period; and
an eighth switch, coupled to the second terminal of the third capacitor, for coupling the second terminal of the second differential input voltage to the second terminal of the third capacitor in the second period.

10. The comparator according to claim 6, wherein the first switch and the second switch are turned on in the first period, and are turned off in the second period.

11. The comparator according to claim 6, wherein the latch is disabled in the first period, and is enabled in the second period.
